(19) United States
(12) Patent Application Publication
(10) Pub. No.: US 2023/0413678 A1
(43) Pub. Date: Dec. 21, 2023

(54) METHOD OF MANUFACTURING AN AMBIENT ENERGY TRANSDUCER, IN PARTICULAR AN AMBIENT ENERGY ELECTRIC ELEMENT

(71) Applicant: E-Convert GmbH, Bergisch Gladbach (DE)

(72) Inventors: HENRIK HENRIKOVYCH SHUMINSKYI, Kakhovka (UA); OLEKSANDR IVANOVYCH HETMAN, Kakhovka (UA)

(21) Appl. No.: 18/339,745

(22) Filed: Jun. 22, 2023

Related U.S. Application Data
(63) Continuation-in-part of application No. 16/077,393, filed on Aug. 10, 2018, now abandoned.

(51) Int. Cl. H10N 35/00

(52) U.S. Cl. CPC H10N 35/101

(57) ABSTRACT

A method of manufacturing an ambient energy converter that includes a supporting substrate of a first conductor material as a first electrode, a layer of ferroelectric material, and a layer of a second conductor material as a second electrode. The two conductor materials have different concentrations of free electrons. The ferroelectric material includes one or more ferroelectric semiconductors. The method includes providing a plate of the conductor material for the first electrode as a supporting substrate, subjecting the carrier substrate to a surface treatment, depositing the layer of ferroelectric material (BTO layer) on a front side of the carrier substrate, masking the edges of the BTO layer on the front side of the carrier substrate while leaving at least one portion located within the edges of the BTO layer free, and applying the conductor material intended for the second electrode to the area kept free of masking.

### CROSS-REFERENCE TO RELATED APPLICATIONS

This application is a continuation-in-part of U.S. patent application Ser. No. 16/077,393, which is a national stage of International Patent Application No. PCT/UA2017/000038, titled “ELECTICAL POWER GENERATOR”, filed Apr. 11, 2017, which claims priority to UAA 2016 04279 filed on Apr. 18, 2016, which are hereby incorporated by reference in their entirety.

### BACKGROUND OF THE INVENTION

### Field of the Invention

The present invention relates to a method for manufacturing an ambient energy converter. In particular, the present invention relates to an ambient energy electric element (i.e. an element drawing electricity from ambient energy) and a method suitable for its manufacture.

The principle of operation of the ambient energy converter, also known as the environmental energy converter, is the operation of the device due to the absorption of energy from the environment in the area where this device is located.

The materials used in the device, the possibility of combining them, as well as the possibility of changing the proportion of materials, and the possibility of changing the design of the device according to the technical task allows the device to be used universally in various applications that require a power supply.

### Description of Related Art

WO 2017/184102 A1 discloses an electric current generator. This electric generator includes a housing with a package of conductive plates of both features, including at least one elementary cell. The elementary cell consists of a layer of a ferroelectric material and two different conductive plates. The plates and layer are arranged in the following order: a first conductive plate—a ferroelectric material—a second conductive plate different from the first. All the plates and the layer in the package are placed close to each other. The conductive plates are made of different conductors with different concentration of free electrons. Ferroelectric semiconductors used as ferroelectric material can be selected from the list of sodium nitrite, semiconductor ceramics based on barium titanate, lithium niobate, potassium niobate, lead titanate and so on.

RU 2419951 discloses a current generator comprising a housing with a package of conductive plates separated by a layer of a ferroelectric material and consisting of different conductors with different concentrations of free electrons. The plates of both signs and the layer are in close contact with each other.

It is known by HEYWANG “Semiconducting Barium Titanate” Journal of Materials Science 6, 1971 pp 1214-1226 that barium titanate is a ferroelectric material with extremely high permittivity (dielectric constant).

It is doped to produce semiconductor ceramics based on barium titanate.

It is known by RU 2162457, IPC (7) C04B35/468, C04B35/64, published on 27 Jan. 2001) to convert the ferroelectric material barium titanate BaTi03 which is a dielectric with a specific electrical resistance of more than 1012 ohm-cm, by so-called forced reduction (RU 2162457, IPC (7) C04B35/468, C04B35/64, published on 27 Jan. 2001) into a ferroelectric semiconductor with a resistivity of 10 ohm-cm to 103 ohm-cm.

It is known by G. G. Emello, T. A. Shichkova “The sol-gel method of preparation of semiconductor barium titanate doped with lanthanum oxide Bal-XLaXTi03 and tungsten oxide BaTil-XWX03 (x=0.001, 0.002)”, Solid State Chemistry and Modem Micro- and Nanotechnology VI International Conference Kislovodsk Stavropol: NCSTU, 2006; pp. 510 to convert the ferroelectric material barium titanate BaTi03 into a ferroelectric semiconductor with resistivity from 10 ohm-cm to 103 ohm-cm by controlling its valence.

### SUMMARY OF THE INVENTION

One object of the present invention is to provide a method of making an ambient energy-electric converter, also referred to as an ambient energy converter, preferably an ambient energy-electric element that draws and provides electricity from ambient energy.

The task is solved by the features of the independent claim. Advantageous embodiments are reproduced in the claims, the drawings and in the following description, including those pertaining to the drawings.

It is important to emphasize that the invention may be realized by a method of manufacturing an ambient energy converter having at least one elementary cell. The ambient energy converter or its elementary cell comprises a plate-shaped carrier substrate of a first conductor material as a first electrode and a layer structure arranged thereon with a layer of ferroelectric material and a layer of a second conductor material different from the first conductor material as a second electrode. The two conductor materials have different concentrations of free electrons. The ferroelectric material preferably comprises one or more ferroelectric semiconductors. Ferroelectric semiconductors used as the ferroelectric material may be selected from the list of sodium nitrite, barium titanate-based semiconductor ceramics, lithium niobate, potassium niobate, lead titanate, and so on.

The process involves first providing a sheet of the conductor material intended for the first electrode as a supporting substrate.

Subsequently, the carrier substrate is subjected to at least one surface treatment.

A layer of ferroelectric material, BTO for short, is then applied to a side of the carrier substrate intended as the front side. This layer can also be referred to as the BTO layer.

It is important to emphasize that the abbreviation BTO can be representative for any ferroelectric material—also material combinations—but especially preferably for a ferroelectric semiconductor, in particular, for barium titanate BaTiO3 or combinations thereof and/or thereof.

Finally, a layer of the conductor material intended for the second electrode is masked within the BTO layer and applied to the front side of the substrate provided with the BTO layer. The masking serves to ensure that there is no contact between the conductor materials of the first and second electrodes outside the BTO layer. Inside the part of the front side of the carrier substrate provided with the BTO layer, the conductor materials of the first and second electrodes are separated from each other by the BTO layer.

The method may have and/or implement individual or a combination of the features described previously and/or subsequently in connection with the ambient energy converter and/or ambient energy electric element and/or ambient energy electric generator, just as the ambient energy converter and/or ambient energy electric element and/or ambient energy electric generator may have and/or implement individual or a combination of multiple features described previously and/or subsequently in connection with the method.

The method and/or the ambient energy converter and/or the ambient energy electric element and/or the ambient energy electric generator may alternatively or additionally have individual or a combination of several features described introductory in connection with the prior art and/or in one or more of the documents mentioned regarding the prior art and/or in the following description regarding the embodiments shown in the drawings.

Additional advantages over the state of the art that go beyond the complete solution of the set task and/or beyond the advantages mentioned above for the individual features are listed below.

### BRIEF DESCRIPTION OF THE DRAWINGS

FIG. 1 is a schematic view an elementary cell of an electricity generator generating electricity from ambient energy, comprising an ambient energy converter housed in a housing 1 according to one embodiment.

FIG. 2 is a schematic view of an arrangement example of several elementary cells of of the embodiment of FIG. 1 connected in series.

FIG. 3 is a schematic view of an arrangement example of several elementary cells of the embodiment of FIG. 1 connected in parallel.

FIG. 4 is a schematic view of an arrangement example of several elementary cells of the embodiment of FIG. 1 connected in series and parallel.

FIG. 5 is a flow diagram of a sequence of a process for manufacturing an ambient energy converter according to the embodiment of FIG. 1.

### DETAILED DESCRIPTION OF THE INVENTION

The invention is explained in more detail below with reference to examples of embodiments shown in the drawing. The size ratios of the individual elements to one another in the figures do not always correspond to the real size ratios, since some shapes are simplified and other shapes are shown enlarged in relation to other elements for better illustration. Identical reference signs are used for elements of the invention which are identical or have the same effect. Further, for the sake of clarity, only reference signs necessary to describe the particular figure are shown in the individual figures. The embodiments shown are merely examples of how the invention can be designed and do not represent a conclusive limitation.

It will be readily understood that the components of the embodiments as generally described and illustrated in the figures herein, may be arranged and designed in a wide variety of different configurations in addition to the described example embodiments. Thus, the following more detailed description of the example embodiments, as represented in the figures, is not intended to limit the scope of the embodiments, as claimed, but is merely representative of example embodiments.

Furthermore, the described features, structures, or characteristics may be combined in any suitable manner in one or more embodiments. In the following description, numerous specific details are provided to give a thorough understanding of embodiments. One skilled in the relevant art will recognize, however, that the various embodiments can be practiced without one or more of the specific details, or with other methods, components, materials, etc. In other instances, well-known structures, materials, or operations are not shown or described in detail to avoid obfuscation. The following description is intended only by way of example, and simply illustrates certain example embodiments.

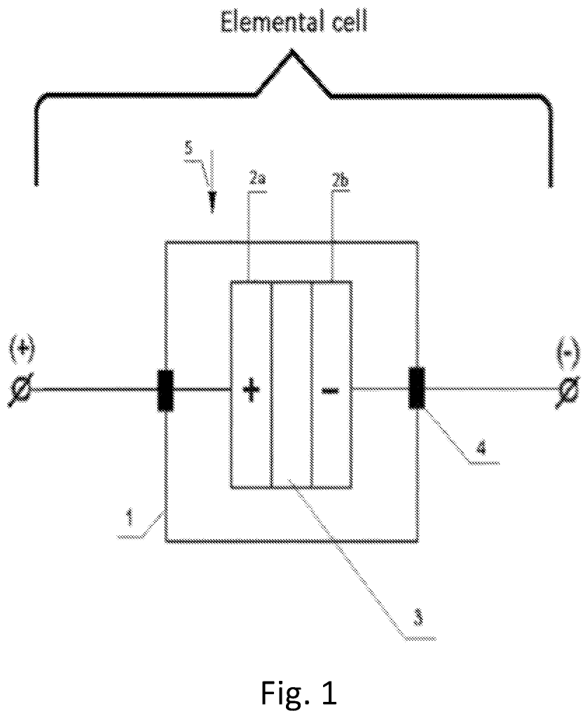

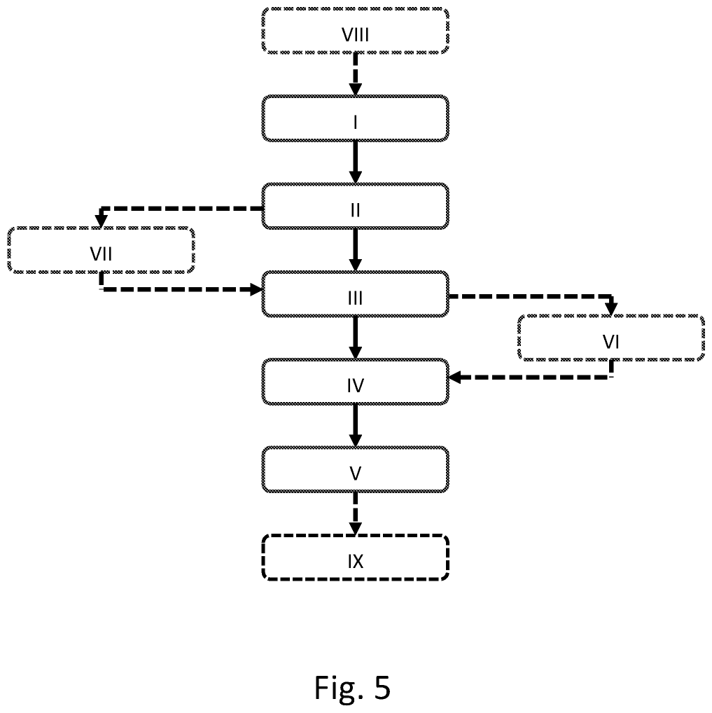

A process shown in FIG. 5 in its sequence in whole or in part is used to manufacture an ambient energy converter. As shown in FIGS. 1-4, the ambient energy converter has a plate-shaped carrier substrate made of a first conductor material as first electrode 2, 2a, 2b, and a layer structure arranged thereon with a layer of ferroelectric material designated as BTO layer 3 and a layer of a second conductor material different from the first conductor material as second electrode 2, 2b, 2a.

The two conductor materials have different concentrations of free electrons. The ferroelectric material preferably comprises one or more ferroelectric semiconductors. Ferroelectric semiconductors used as the ferroelectric material are advantageously selected from the list of sodium nitrite, barium titanate-based semiconductor ceramics, lithium niobate, potassium niobate, lead titanate, etc.

In a first process step I, the process provides for a plate of the conductor material provided for the first electrode to be provided as a carrier substrate.

A second process step II following the first process step I provides for subjecting the carrier substrate to at least one surface treatment. The carrier substrate is subjected, for example, at least on its side intended as the reverse or rear side, to a surface treatment using blasting technology. Preferably, shot peening, especially preferably glass shot peening is applied as surface treatment at least to the back side of the carrier substrate. Alternatively or additionally, preferably following a first surface treatment by abrasive blasting, the carrier substrate is degreased as, for example, a second surface treatment. Advantageously, the degreasing is carried out using H O₂₂.

A third process step III, following the second process step II, provides for application of the layer of ferroelectric material, referred to as BTO layer for short, preferably a ferroelectric semiconductor, particularly preferably barium titanate BaTiO₃ referred to as BTO for short, to a side of the carrier substrate intended as the front side.

In a fourth process step IV following the third process step III, masking of at least the edges of the BTO layer on the front side of the carrier substrate is carried out while keeping free at least one portion located within the edges of the BTO layer.

A fifth process step V following the fourth process step IV provides for application of the conductor material intended for the second electrode to the portion kept free of the masking.

Accordingly, the method provides for first providing a plate of the conductor material provided for the first electrode as a supporting substrate.

Subsequently, the carrier substrate is subjected to at least one surface treatment.

Then, a layer of ferroelectric material, preferably a ferroelectric semiconductor, particularly preferably barium titanate (BaTiO₃), BTO for short, is applied to one side of the carrier substrate intended as the front side. This layer is also referred to as the BTO layer.

It is important to emphasize that the abbreviation BTO can be representative for any ferroelectric material—also material combinations—but especially preferably for a ferroelectric semiconductor, in particular for barium titanate BaTiO₃ or combinations thereof and/or thereof.

Finally, a layer of the conductor material intended for the second electrode is applied, preferably masked, within the BTO layer to the front side of the substrate provided with the BTO layer. The masking serves to ensure that there is no contact between the conductor materials of the first and second electrodes outside the BTO layer. Inside the part of the front side of the carrier substrate provided with the BTO layer, the conductor materials of the first and second electrodes are separated from each other by the BTO layer.

The process can provide an additional process step VI arranged between the third process step III and the fourth process step IV. In this step, after application of the layer of ferroelectric material (BTO layer) to the side of the carrier substrate intended as the front side, and before application of the conductor material intended for the second electrode to the part kept free of the masking, a quality control of the BTO layer is carried out by checking the BTO layer at least within the part kept free of the masking for at least sectional homogeneity of its layer thickness and/or at least sectional closed covering of the carrier substrate.

This serves to ensure that no contact points occur between the two conductor materials during the subsequent application of the conductor material intended for the second electrode. Contact points between the conductor materials for the first and second electrodes, both within the BTO layer and laterally around the BTO layer, lead to a short circuit between the two electrodes and thus to the rejection of the part of the ambient energy converter manufactured to date.

The process can provide an additional process step VII arranged, for example, between the second process step II and the third process step III. This step provides for the BTO layer to be doped before the conductor material intended for the second electrode is applied to the area kept free of masking, particularly preferably before masking.

This additional process step VII can alternatively be carried out independently of the third process step III outside the series of first and second process steps I, II carried out to date. In such an additional process step VII, the ferroelectric material intended for the BTO layer is doped before the BTO layer is applied.

Regardless of whether the additional process step VII is carried out after or before the third process step III, a doping process is carried out in the additional process step VII before the application of the conductor material provided for the second electrode with the aim of obtaining an average Nb concentration in the BTO layer of 0.3 at %. An optimization of the Nb content is advantageously obtained by means of EDS measurements.

The application of the ferroelectric material to the BTO layer in the third process step III and/or the application of the conductor material provided for the second electrode in the fifth process step V is advantageously carried out by vapor deposition.

For vapor deposition of either the ferroelectric material to the BTO layer or the conductor material intended for the second electrode, or the ferroelectric material to the BTO layer and the conductor material intended for the second electrode, CVD (chemical vapor deposition) or PVD (physical vapor deposition) can be used.

Preferably, physical vapor deposition (PVD) takes place as a vapor deposition method in the third process step III and/or in the fifth process step V.

PVD as a preferred vapor deposition method includes in particular:
Evaporation processes briefly summarized under the term vacuum evaporation, such as thermal evaporation, electron beam evaporation, pulsed laser ablation (atoms and ions are evaporated by a short, intense laser pulse), arc evaporation (arc-PVD; Arc PVD; atoms and ions are removed from the starting material and transferred to the gas phase by a strong current flowing between two electrodes during an electrical discharge like lightning), molecular beam epitaxy.
Sputter deposition, also known as cathode sputtering, in which the starting material is atomized by ion bombardment and transferred to the gas phase, as well as ion beam assisted deposition (IBAD), in which deposition also takes place with simultaneous synthesis of metal atoms and gases on substrates, but in addition the gas molecules transferred to the gas phase are dissociated by ion sources, ionized and simultaneously offered to a usually heated substrate surface.
Ion plating, in which a higher-quality metal layer is deposited on another metal with the aid of plasma. First, a so-called soft etch is performed by sputtering, in which the substrate surface is cleaned by ion bombardment from the plasma. Metal vapor is then supplied from an evaporator source. This partially ionizes in the plasma and is accelerated by an electrical bias voltage between 0.3 and 5 kV at the preferably preheated substrate on its surface, forming a layer of the vaporized material on the substrate. As a result of the constant bombardment with metal ions, part of the substrate or layer is repeatedly removed, i.e. sputtered off. The dissolved atoms condense again on the substrate and contribute to the layer formation. The continuous ion bombardment modifies the layer properties. Among other things, it can improve the adhesion of the layer. The resulting layer structure depends on the temperature of the substrate. Preferably, ion plating is carried out under a working pressure of between 2 Pa and 8 Pa, particularly preferably of 5 Pa.
Reactive Ion Plating (RIP). In this process, a reactive gas is additionally introduced into the plasma, which also ionizes, reacts with the atomized metal and forms a layer of the resulting compound. In this way, a titanium nitride layer can be created from titanium vapor and introduced nitrogen.
ICB (ionized cluster beam) technique, also ICBD (ionized cluster beam deposition), whereby it is a modified vapor deposition process for the production of thin films of metals, dielectrics and semiconductors at low substrate temperatures. The crucible used with the molten starting material is initially kept closed. Evaporation of the material and heating of the material vapor creates an overpressure in the sealed crucible. When a process-specific pressure is reached, the vapor for the coating is discharged through a nozzle under adiabatic expansion. This results in a kind of condensation in the gas space, during which electrically neutral atomic clusters consisting of approx. 500 to 2000 atoms are formed. These neutral atomic clusters are partially ionized in the gas space by collisions with an electron beam, preferably by about 5% to 35%. They are then accelerated towards the substrate surface in an electric field. Upon impact with the substrate surface, these atomic clusters partially decay, spreading over the surface and forming a condensed layer. Via the accelerating voltage of the electric field, it is possible to vary the average energy of the atomic clusters from the purely thermal energy to more than 200 eV per atom. This allows controlled deposition of crystalline layers and epitaxy. The coating properties (film conformality, etc.) of the process are mainly influenced by the characteristic structure and the effect of ionization and acceleration of the atomic clusters. However, the acceleration voltage can also be used to adjust the energy of the clusters in such a way that, similar to sputtering, a cleaning or even sputtering effect of the substrate is achieved.

The method preferably provides that nickel (Ni), silver (AG), brass, aluminum (Al), alloyed iron (Fe), in particular steel, are used as conductor materials, whereby conductor materials with different concentrations of free electrons are used for the first and for the second electrode, preferably different conductor materials.

It is important to emphasize that any material that has the ability to conduct electricity can be used as a material for the anode (+) and cathode (−).

The process particularly advantageously provides that at least parts of the process sequence take place under vacuum conditions, particularly advantageously under high vacuum conditions.

Particularly preferably, at least parts of the process take place under vacuum, preferably under a gas pressure that is lower than the ambient air pressure, briefly referred to as ambient pressure.

The process advantageously provides that at least parts of the process sequence take place under an inert gas atmosphere, particularly preferably under a noble gas atmosphere.

A preferred embodiment of the process provides that, in an additional process step VIII preceding the first process step I, the carrier substrate is arranged alone or together with, for example, other carrier substrates on a device also referred to as a carrier, in order to run through the treatment steps provided in the various process steps or to carry them out in succession.

It is important to emphasize that the ambient energy converter or the ambient energy electric element operates due to an influx of energy from the environment.

The ambient energy converter or the ambient energy electric element converts ambient energy, such as gravitational energy, cosmic rays, electric fields, magnetic fields in the environment, for example, in the form of electromagnetic waves of different frequencies, from extremely low mechanical vibrations, sound, radio waves, light radiation,—from infrared to ultraviolet, as well as the entire range of X-rays, into electricity.

The ambient energy converter and the ambient energy electric element, respectively, operate in strict compliance with the law of conservation of energy, charging by electromagnetic oscillations and wide-range pulses. They convert a wide range of low-potential environmental energies into electrical energy.

The method allows the production of an ambient energy converter or an ambient energy electric element, which can be used, for example, in a power generator.

Such a power generator can also be used as a power source in any device that requires electrical energy.

These can be mobile devices, home appliances, solar panels, electric vehicles, autonomous power systems for premises, as well as for use in the military industry.

These devices can be charged independently of the energy of their environment and operate autonomously, without further external charging. If necessary

Such a device can also be connected to other power sources depending on the programmed power characteristics.

The devices can be used in places far away from civilization.

For example, such devices can be used in space, on the ground and under the earth, on the water and under the water, in the human body, to name just a few conceivable applications.

The main advantage of the power generator is the ability to work autonomously far from civilization, because it is charged by the energy of the environment. In other words, it draws the electrical energy it provides from the energy of the environment.

This principle of operation does not violate the second law of thermodynamics and its principles. So all solar collectors work on the same principle. The only difference is the limited possibilities of charging with the energy of the environment.

For example, solar panels work worse in winter. The ambient energy converter and a power generator comprising at least one of them can operate in temperature ranges from −270 to +800.

The ambient energy converter and a current generator comprising at least one of them operate according to the law of conservation of energy.

Namely:—according to the law—Lavoisier, the law—Lavoisier—Laplace, the law—Lavoisier—Laplace and Hess. A law discovered from the basic laws of thermochemistry.

The selected materials and their studied capabilities and nature allow, in pure or mixed form, to achieve the desired properties according to the performance specification.

One of the capabilities of materials to generate electricity is the ability to absorb the energy of the environment and be charged.

A wide range of absorbed energy—creates a potential difference. This in turn sets these materials in motion. During operation, the potential difference of the energy in the environment ensures that the ambient energy converter works and energy is converted into direct current.

Such a power generator comprising the ambient energy converter or the ambient energy electric element comprises, for example, a housing 1 accommodating the ambient energy converter or the ambient energy electric element.

The method may comprise at least one additional process step IX downstream of the fifth process step V for producing an ambient energy electric generator.

In this additional process step IX, the ambient energy converter manufactured to date or the ambient energy-electric element manufactured to date can be inserted into a housing 1. Thereby, an elementary cell of an ambient energy electric generator is obtained.

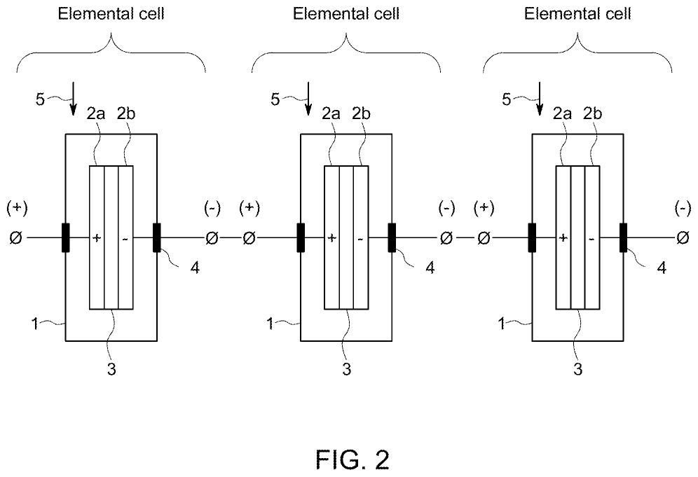

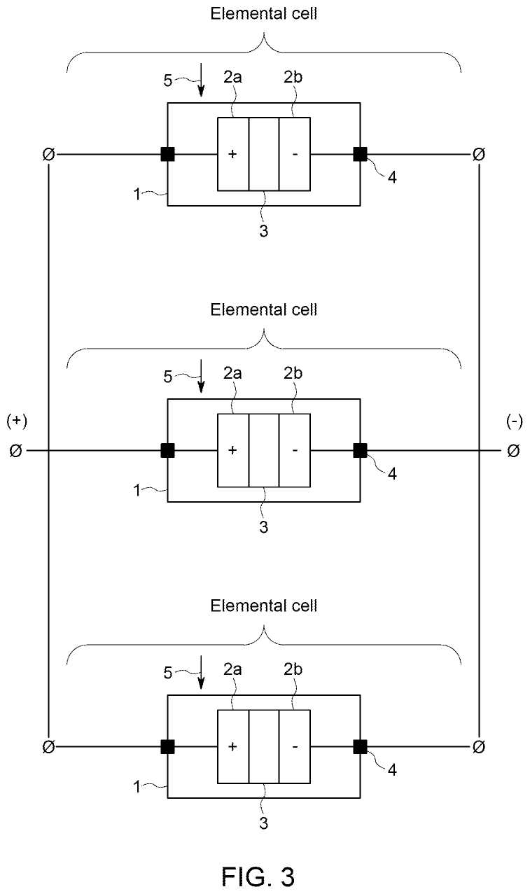

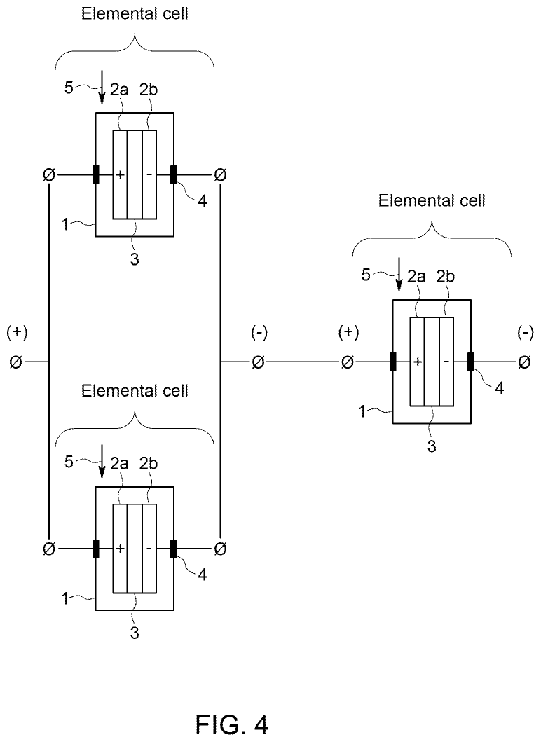

The method thus permits the production of an ambient energy electric generator—in short a current generator—shown in FIG. 2, FIG. 3, FIG. 4, FIG. 5 shown in whole or in parts, ambient energy electric generator—in short current generator—with a housing 1 and the ambient energy converter housed therein with the carrier substrate made of the first conductive material as the first electrode and the layered structure made thereon of BTO layer and the second conductive material for the second electrode as a package of conductive plates of both features, which consists of a layer of a ferroelectric material 3 and two different conductive plates arranged in the following order: a conductive plate 2—a ferroelectric material 3—a conductive plate 2 different from the first one.

All layers are tightly bonded and closely attached to each other, and the first and second electrodes, referred to as conductive plates 2, are made of different conductors with different concentrations of free electrons. Ferroelectric semiconductors used as ferroelectric material for BTO layer can be selected from the list of sodium nitrite, barium titanite based semiconductor ceramics, lithium niobate, potassium niobate, lead titanite and so on.

Accordingly, the current generator comprises the ambient energy converter housed in a housing as a unit cell. The current generator can have several elementary cells. These can be electrically arranged in series (FIG. 2), in parallel (FIG. 3), or a combination of series and parallel (FIG. 4).

It is important to emphasize that the following procedural steps can be performed:
Provision of nickel (Ni) sheets as carrier substrates forming the first electrode of any ambient energy-electric transducer or ambient energy-electric element, for example in a dimension of 100×100 mm. Technical quality is sufficient, without special requirements for composition and impurities. The surface roughness is advantageously as low as possible.
Glass bead blasting of the backing substrate to improve temperature coupling.
Degrease the carrier substrate with H O₂₂.
Design and manufacture of a special carrier for automated handling of the carrier substrates, for example with a robot arm of a vacuum coating line.
Design and manufacture of two ceramic masks for masked Ag and Al deposition. For example, for carrier substrates with dimensions of 100×100 mm, the mask cutout measures 90×90 mm. Advantageously, a mask for fabricating a second electrode referred to as a full-area blanket electrode, and a mask having a grid structure for depositing a second electrode referred to as a single-electrode array blanket electrode can be provided.
Provide a barium titanate (BaTiO3), or BTO target for short, for PVD coating of the supporting substrate with the BTO layer in a first vacuum chamber.
Provide a niobium (Nb) target for Nb doping of at least the BTO layer.
Assembly Nb target, process setup doping process with target average Nb concentration in BTO layer 0.3 at % Optimization Nb content using EDS measurements.
Provision and assembly of a silver (Ag) target as conductor material for the second electrode in a second vacuum chamber. Process start-up including rate and layer thickness distribution.
Alternative provision and assembly of an aluminum (Al) target as conductor material for the second electrode in a second vacuum chamber. Process start-up including rate and layer thickness distribution.

Expected layer and doping homogeneities on diameter 100 mm

| Layer | Homogeneity |
|---|---|
| BTO | ±30% |
| Nb doping | ±8% based on absolute content in BTO layer |
| | ±38% based on relative content in the BTO layer |
| Ag top | coating ±15% |
| Al top coating | ±3% |

Parameter variations of the carrier substrate coatings:

| ProbeNb doping | BTO coating | Cover electrode |
|---|---|---|
| aWith | Standard | Al Single electrode array |
| bWith | Intermediate polishing | Al full surface |
| cWith | Intermediate polishing | Ag single electrode array |
| dWithout | Standard | Al Single electrode array |
| eWithout | Intermediate polishing | Al full surface |
| fWithout | Intermediate polishing | Ag single electrode array |

The BTO coating is preferably applied over the entire surface. The BTO layer advantageously occupies the carrier substrate completely, but at least the portion occupied by the second conductor material for the second electrode during application plus an edge surrounding it.

The Al or Ag coating is masked to avoid contact between the second electrode, also known as the cover electrode, and the carrier substrate.

Due to the flatness of the Al or Ag cover electrode, the risk of a short circuit between the carrier substrate, which is designed as a Ni substrate for example, and the second electrode, which is designated as the cover electrode, is high due to defects in the carrier substrate or in the BTO layer. Advantageously, therefore, a multi-stage process for BTO deposition with “intermediate polishing” between the individual stages of deposition is optionally carried out. Optionally, it is also possible to deposit an array of single electrodes instead of a flat cover electrode in order to avoid using single electrodes with short circuits.

For quality control purposes, the following parameters can be recorded during the process sequence:
Layer thickness distribution BTO.
Layer thickness distribution Al and Ag.
three times EDS measurements for optimization Nb content.
radially distributed EDS measurement with three measuring points to determine distribution of the Nb content across the carrier substrate or its front side.
XRD: two samples BTO (with and without Nb).
SEM with ion preparation: two samples BTO (with and without Nb).

For quality control within the scope of substrate coatings, the following parameters can be recorded:
the thickness of the BTO layer on a Si reference substrate located outside the sample area can be determined.
the thickness of the Ag and/or Al conductor material for the second electrode on a Si reference substrate located outside the sample area can be determined.
The electrical resistance between the carrier substrate and the second electrode, also known as the cover electrode, can be measured, for example, using a multimeter.

For example, a manufacturing sequence may provide:
Order/Delivery Nb Target.
Research/order/delivery Ni carrier substrates.
Design/manufacture customized carriers.
Coordination design/order/manufacture shadow masks.
Substrate cleaning.
Preparation BTO process.
Test coatings.
BTO Coating Carrier Substrates.
Al metallization first batch carrier substrates.
Commissioning co-Sputter process with Nb.
Composition Optimization.
Nb:BTO Nb:BTO coating Customer substrates.
Al metallization second batch customer substrates.
Ag Metallization Customer Substrates.

The process allows the production of an electricity generator drawing electricity from ambient energy.

The electric current generator consists of a housing 1, which houses an ambient energy converter manufactured according to the process.

The ambient energy converter can be described as a package of conducting plates of both polarities as electrodes separated by a layer of stabilized single crystal ferroelectric. All layers in the package are in close contact with each other. The plate pack accommodated in the housing 1 forms an elementary cell 5. The plate pack is made layer by layer of a ferroelectric material, comprising two metal plates of dissimilar conductor material with a significant difference in the concentration of free electrons. According to the method, the plate pack is built up as a layered structure on a carrier substrate of a first conductor material as the first electrode 2, 2a, 2b. The layers comprising the carrier substrate are arranged in the following order: a conductive plate of a first conductor material as the carrier substrate forming the first electrode—a BTO layer of ferroelectric material—a layer of conductor material different from the first conductor material serving as the second electrode. The elementary cells 5 can be connected to an electrical energy source in series (FIG. 2) or in parallel (FIG. 3) or in combination of series and paralle (FIG. 4). In a combined arrangement, some elementary cells 5 are connected in series and some are connected in parallel. In the BTO layer 3, stabilized single crystals of ferroelectric materials are replaced by stabilized single crystals of ferroelectric semiconductors, such as sodium nitrite, semiconductor ceramics based on barium titanate, lithium niobate, potassium niobate, lead titanate, and so on. This reduces the internal electrical resistance of the ambient energy converter and thus of the elementary cell 5. Furthermore, this increases the specific electrical power of the ambient energy converter and thus of the elementary cell 5 when it is connected to an electrical load.

A special feature of the ambient energy converter and thus of the elementary cell 5 is the replacement of stabilized single crystals of ferroelectric materials by stabilized single crystals of ferroelectric semiconductors, such as sodium nitrite, semiconductor ceramics based on barium titanate, lithium niobate, potassium niobate, lead titanate, and so on.

It is known that there are ferroelectric materials which also possess semiconductor properties, the so-called ferroelectrics—semiconductors which, according to the value of electrical resistivity (10-2-107 Ohm-cm), occupy an intermediate position between conductors and insulators. For example, sodium nitrite (NaNO2), semiconductor ceramic materials based on lithium niobate, potassium niobate, lead titanate, barium titanate and many others (see V. M. Fridkin Ferroelectric Semiconductors.—M.: Nauka, 1976.-408 p. V. V. Ivanov, A. A. Bogomolov, Ferroelectric Semiconductors, Kalinin, Kalinin University Press, 1978, 96 p.).

In particular, the ferroelectric material barium titanate BaTiO3 is a dielectric with a resistivity higher than 1012 ohm-cm. However, it is possible to convert it into a ferroelectric semiconductor with a resistivity of 10-103 ohm-cm, for example, by forced recovery (see patent RU 2162457, IPC (7) C04B35/468, C04B35/64, published on 27 Jan. 2001) or by controlling its valence (see Solid State Chemistry and Modem Micro- and Nanotechnology VI International Conference Kislovodsk Stavropol: NCSTU, 2006. 510 pp. The sol-gel method of preparation of semiconductor barium titanate doped with lanthanum oxide Bal-XLaXTiO3 and tungsten oxide BaTil-XWXO3 (x=0.001, 0.002), G. G. Emello, T. A. Shichkova).

BaTiO₃ is doped to produce semiconductor ceramics based on barium titanate.

Titanium ions Ti⁴⁺ are replaced by W⁶⁺Sb⁵⁺, Nb⁵⁺, Ta⁵⁺, etc., for this purpose. ions. Barium ions Ba²⁺ are replaced by Mn⁴⁺, La³⁺, Nd³⁺Y³⁺Gd³⁺ ions and others.

The concentration of the dopant elements is typically less than 0.3 atomic percent.

The causal relationship is as follows:
The use of ferroelectric semiconductors with electrical resistivity less than 107 ohm-cm as the active elementary cell element instead of ferroelectric materials, which are pronounced dielectrics with electrical resistivity up to 1016 ohm-cm, makes it possible to reduce the internal electrical resistance of the elementary cell and obtain larger specific electrical currents on the same pairs of current collectors of the elementary cell.
The increase in specific electric currents at constant potential difference leads to a natural increase in specific electric power of an elementary cell by more than two times compared to a barium titanate prototype.
The increase of the specific electric power of an elementary cell makes it possible to expand the possibilities of practical use of the power generator both technically and economically.

The generator for electrical energy consisting of at least one elementary cell is shown in FIG. 1. This generator consists of a housing 1, in the interior of which two electrodes 2, 2a, 2b, also referred to as a conductor pair, are arranged, which consist of different conductor materials with different concentrations of free electrons. A ferroelectric semiconductor 3 is located between the electrodes 2, 2a, 2b. Insulators 4 are used to pass electrical contacts connected to the electrodes 2, 2a, 2b through the housing 1. The electrical contacts serve both to interconnect several elementary cells (FIG. 2, FIG. 3, FIG. 4) and to connect electrical loads.

The following barium titanate-based semiconductor ceramics are given as examples of ferroelectric semiconductors used to manufacture the elements of the electric power generator:
Barium titanate doped with niobium (Nb) with atomic concentration of 0.220% and resistivity of 6470 Ohm-cm;
Barium titanate doped with lanthanum (La) with a concentration of 0.125 atomic % and a resistivity of 883,500 ohms-cm.

Reference samples of barium titanate prototypes are prepared using barium titanate with a resistivity of 2710000000 ohms-cm.

Iron-nickel is used as a pair of unequal conductors. The current generator consists of at least one elementary cell 5. The elementary cell 5 is produced by successive vacuum deposition on the anti-adhesive base layer with a surface area of 1 dm².

The layer structure on the carrier substrate serving as the first electrode 2, 2a, 2b and consisting of the first conductor material advantageously has the following layer thicknesses: The layer of the second conductor material provided as the second electrode 2, 2b, 2a is advantageously formed with a thickness of 9-10 microns. A BTO layer of a ferroelectric semiconductor is formed with a thickness of less than 1 micron, thereby providing a continuous, non-porous, uniform coating.

### Example 1

Fabrication of the elemental cell reference sample as a barium titanate prototype. A mask with a surface area of 1 dm2 is applied to the polished polytetrafluoroethylene basecoat, which has been treated with polymethyl, and an iron layer with a thickness of 9-10 microns is sprayed on. The mask is removed and another layer of barium titanate is sprayed on, creating a continuous, uniform, non-porous coating up to 1 micron thick.

Then the mask is put back and a nickel layer with a thickness of 9-10 microns is sprayed on. The mask is removed and a finishing element is separated from the base coat using a vacuum suction cup. Using diethyl ether, polymethylsiloxane traces are removed from the surface layer of iron and the residual diethyl ether is removed by blowing dry air. Then the unit cell is placed between pole terminals made of iron or nickel. The obtained electric current generator is connected to a power source.

### Example 2

Fabrication of an elementary cell from barium titanate doped with niobium.

### Example 3

The unit cell is fabricated by the technique described in Example 1, using barium titanate doped with niobium instead of barium titanate.

Table 1 shows the relationship between the electrical power (mW) and the values of voltage (V) and electrical current (mA) of a unit cell at an external load of 1000 ohms of ferroelectric semiconductor materials relative to a reference sample of the barium titanate prototype.

The working time of each ferroelectric semiconductor, which is part of a single unit cell, has been studied. In the temperature range from −20 to +110 degrees Celsius, each elementary cell is operated continuously for more than 18000 hours.

TABLE 1

| | electric | | |
|---|---|---|---|
| ferroelectric | power | Voltage | Current |
| material | (mW) | (V) | (mA) |
| Barium titanate | 1.129 | 1.062 | 1.063 |
| Barium titanate | 2.358 | 1.060 | 2.225 |
| doped with niobium | | | |
| (Nb) | | | |
| Barium titanate | 2.111 | 1.061 | 1.990 |
| doped with | | | |
| lanthanum (La) | | | |

As shown in Table 1, the electrical power increases dramatically when ferroelectric semiconductors are used. When niobium (Nb) doped barium titanate is used, the electrical power of the generator element cell increases 2,088 times compared to the barium titanate prototype. When barium titanate doped with lanthanum (La) is used, the electrical power of the generator elementary cell increases 1869 times compared to the barium titanate prototype. According to its practical application, the current generator has a significant advantage over the barium titanate prototype.

Examples of variations in the manufacturing process and the ambient energy converter that can be produced by it are given below.

A particularly preferred material combination for the ambient energy converter is silver (Ag)-BaTiO3-aluminum (Al).

Alternative material combinations are
Silver-BaTiO3-brass.
Brass-BaTiO3-Silver.
Nickel-BaTiO3-Aluminum.
Aluminum-BaTiO3-Nickel.
Fe, (alloyed)-BaTiO3-brass.
Fe, (alloyed)-BaTiO3-aluminum.
Fe, (alloyed)-BaTiO3-Nickel.

It is important to emphasize at this point that other options are also possible.

When iron is used as a conductor material, it is preferred as a carrier substrate.

In principle, any conductive materials can be used as anode and cathode for the two electrodes.

The first material is always used as a carrier substrate.

The first material, used as a support substrate, must be degreased, for example, with hydrogen peroxide (H₂O₂).

A preferred embodiment of the process for manufacturing an ambient energy converter using the particularly preferred material combination silver (Ag)-BaTiO3-aluminum (Al) provides for the following:

For the support substrate serving as the first electrode 2, 2a, 2b, a 1 mm thick silver plate with dimensions of 10 cm×10 cm (100 mm×100 mm) is used.

Thicknesses can be adjusted according to the set technical specifications.

As a BTO layer, BaTiO3 is deposited on the silver plate in a layer thickness of 1 micrometer to 10 micrometers or more by sputter deposition (sputtering).

Thicknesses can be adjusted according to the set technical specifications.

The third material layer serving as the second electrode 2, 2b, 2a, made of aluminum as a conductor material different from the conductor material of the supporting substrate, can also be applied to the BTO layer by sputter deposition (sputtering) in a thickness of 1 micron to 10 microns or more.

The thicknesses of the layers, especially the BTO layer and the layer forming the second electrode 2, 2b, 2a, including the thickness of the supporting substrate can be adjusted according to the set technical specifications.

The main requirement in the manufacture of the layer structure is uniform coverage, in particular of the BTO layer. To avoid direct contact between the conductor materials of the first electrode 2, 2a, 2b and the second electrode 2, 2b, 2a, the BTO layer must be free of gaps, i.e. free of through-holes in the BTO layer. This can be provided, if necessary, by an additional process step VI in the process sequence serving quality control.

For application (sputtering) of the coating structure,—at least one vacuum spray chamber can be used.

Advantageously, a high-vacuum chamber with the lowest possible gas pressure in the working chamber is used.

A continuous uniform coating is achieved with a high vacuum coating.

The coating is advantageously carried out in the absence of ambient air. It is advantageous to provide a noble gas or inert gas atmosphere, in particular argon.

The barium titanate (BaTiO3) of the BTO layer is crystalline.

The desired result is achieved by the crystal lattice that forms during application.

BaTiO3 is a ferroelectric semiconductor by nature.

Barium titanate (BaTiO3) acts as a ferroelectric semiconductor even after sputtering.

Barium titanate (BaTiO3) with its universal properties is used today in various fields, in electronics and microelectronics (sensors, actuators, capacitors), biomedicine (implants).

One of the properties of barium titanate (BaTiO3), as a so-called synoelectric semiconductor in a structure where metals play the role of anode and cathode, is to absorb low potential energy from the environment and store it in itself.

For example—in the examples given (BaTiO3) and its properties, allow to record the effect of light, as well as electromagnetic waves of different frequencies, from extremely low mechanical vibrations, sound, radio waves, up to light radiation—infrared to ultraviolet. And also the properties of (BaTiO3) as a material, which work in memory devices, allow the use of (BaTiO3) in electronics and microelectronics. For example, in capacitors as well as in the ambient energy converter produced by the process.

Ferroelectric semiconductors as nanostructured ferroelectric materials can solve many engineering problems to reduce the size of devices.

The ambient energy converter made according to the method and the power generator comprising the same as proposed differs from other alternative sources of electric power generation in that it uses ferroelectric semiconductors that enable the ambient energy converter to be charged from low potential ambient energy.

At its core, the ambient energy converter is partly a capacitor, meaning it has the ability to accumulate and store energy.

The main difference is that the capacitor is charged from the power grid, while the ambient energy converter is charged with low potential energy, cosmic wave beams, electric and magnetic fields in the environment.

This principle does not violate the law of conservation of energy and the second law of thermodynamics.

Barium titanate (BaTiO3) is a unique and versatile material whose capabilities have not been fully explored to date.

For example, barium titanate (BaTiO3) exhibits a photorefractive effect, also known as a photorefractive effect, which is noticeable in a local change in the refractive index as a function of the light wave incident on it.

Thus, the light beam itself changes the conditions of its propagation.

This property of light acting on itself can be used to perform optical functions such as phase conjugate mirrors (which reflect light back in the direction from which it came), optical computers, optical switches, dynamic holograms, and especially holographic memory devices.

In the present case, the photorefractive effect is one of the ways of absorption and conservation of barium titanate, absorbing energy with low potential from the environment and storing it in itself.

The method may alternatively or additionally have individual or a combination of several features mentioned by way of introduction in connection with the prior art and/or in one or more of the documents mentioned with respect to the prior art and/or in the preceding description or the following claims.

The invention may be realized by or in connection with an ambient energy converter described above or a power generator comprising at least one such converter.

Additionally, beyond a complete solution of the task underlying the invention is a use of new materials, in particular ferroelectric semiconductors. These materials have not previously been used for the creation and provision of direct current electrical energy.

This invention has a number of advantages over other power sources, such as environmental friendliness, versatility of use, and low production costs.

Other advantages include:
Similar energy sources do not exist today, the proposed ambient energy converters, ambient energy electric elements and the power generators based on them, in short ambient energy converters, have nothing to do with galvanic batteries (batteries, accumulators, etc.).
The ability to recharge itself and generate direct current allows cell phones, computers and other devices to operate offline.
The ambient energy converters allow you to work offline for at least 2 years.—If necessary, the life of the ambient energy device can be extended.
No cost in power generation—ambient energy converters are charged independently and absorb ambient energy.
Low production costs of power supplies—in all leading positions of ambient energy converters production costs of ambient energy converters do not exceed the cost of production of conventional batteries (batteries and accumulators).
Unlimited possibilities of their design—from traditional forms in the form of generally accepted galvanic cells to the necessary forms determined by the specifics of their application.
Installations can be multiplied and divided, creating the necessary parameters to solve different requirements—which allows ambient energy converters to be used in different devices and meet all the requirements necessary for comfortable operation of each device.
The ambient energy converters are short-circuit resistant. Short circuits do not affect the further operation of ambient energy converters, as they provide the same power almost immediately even after several short circuits.
Long life without preventive maintenance,—Due to the absence of moving parts and pieces, the ambient energy converter does not require maintenance.
A diverse range of device applications from batteries in hearing aids, telephones, computers, miner's flashlights, car batteries to lighting and space heating.
Absolute communication capabilities—given the widest range of convertible energy of the environment, it is possible to use the ambient energy converters in all existing conditions and in different directions where power sources are needed.
The new technology makes it possible to generate the electricity needed for household appliances in a technologically advanced and cost-effective way.
The proposed technology is absolutely independent and autonomous for long-term operation—the ambient energy converters do not need to be charged with fuel or electric current
There is no need to dispose of hazardous waste—the complete absence of waste and the need for conventional fuel and so on.—, which makes the operation of ambient energy converters environmentally friendly.
An effective advantage of the proposed ambient energy converters is that they will be able to ensure the operation of all devices in autonomous mode—which will be crucial in places far from civilization, as well as in military and tourist conditions.

The invention is not limited by the description based on the embodiments. Rather, the invention encompasses any new feature as well as any combination of features, which in particular includes any combination of features in the claims, even if that feature or combination itself is not explicitly stated in the claims or embodiments.

The invention is particularly applicable commercially in the field of manufacturing and operation of plants and devices for the provision of electrical energy, where, for example, electrical consumers have to be supplied with electricity far from a connection possibility to a power grid.

The invention has been described with reference to preferred embodiments. However, it is conceivable to one skilled in the art that variations or modifications of the invention may be made without departing from the scope of protection of the claims below.

What is claimed is:

1. A method of manufacturing an ambient energy converter comprising a plate-shaped supporting substrate of a first conductor material as a first electrode and a layer structure arranged thereon with a layer of ferroelectric material and a layer of a second conductor material different from the first conductor material as a second electrode, wherein the two conductor materials have different concentrations of free electrons, wherein the ferroelectric material comprises one or more ferroelectric semiconductors, and wherein ferroelectric semiconductors used as ferroelectric materials are selected from the list of sodium nitrite, barium titanate-based semiconductor ceramics, lithium niobate, potassium niobate, lead titanate, wherein the method comprises the steps of:
providing a plate of the conductor material intended for the first electrode as a supporting substrate;
subjecting the carrier substrate to at least one surface treatment;
depositing the layer of ferroelectric material (BTO layer), on a front side of the carrier substrate;
masking at least edges of the BTO layer on the front side of the carrier substrate while leaving at least one portion located within the edges of the BTO layer free; and
applying the conductor material intended for the second electrode to the area kept free of masking.

2. The method according to claim 1, wherein after depositing the layer of ferroelectric material (BTO layer) to the front side of the carrier substrate, and before the application of the conductor material intended for the second electrode to the portion kept free of the masking, a check of the BTO layer is carried out at least within the portion kept free of the masking for at least sectional homogeneity of its layer thickness and/or at least sectional closed covering of the carrier substrate.

3. The method according to claim 1, wherein, as an additional process step, the BTO layer is doped before the conductor material intended for the second electrode is applied to the portion kept free of the masking.

4. The method according to claim 1, wherein, as an additional process step, the ferroelectric material intended for the BTO layer is doped prior to the deposition of the BTO layer.

5. The method according to claim 1, wherein the application of the ferroelectric material and/or the application of the conductor material provided for the second electrode is carried out by vapor deposition.

6. The method according to claim 5, wherein a physical vapor deposition (PVD) is used as the vapor deposition method.

7. The method according to claim 1, wherein a rear side of the carrier substrate is subjected to a surface treatment by abrasive blasting.

8. The method according to claim 1, wherein the carrier substrate is degreased as a surface treatment.

9. The method according to claim 1, wherein nickel (Ni), silver (AG), brass, aluminum (Al), and alloyed iron (Fe), are used as conductor materials, wherein different conductor materials are used for the first and for the second electrode.

10. The method according to claim 1, wherein nickel (Ni), silver (AG), brass, aluminum (Al), and steel, are used as conductor materials, wherein different conductor materials are used for the first and for the second electrode.

11. The method according to claim 1, wherein at least parts of the process take place under vacuum conditions.

12. The method according to claim 1, wherein at least parts of the process take place under an inert gas atmosphere.

13. The method according to claim 1, wherein at least parts of the process take place under a noble gas atmosphere.

14. The method according to claim 1, wherein at least one carrier substrate is arranged on a carrier, in order to run through the treatment steps provided in the various method steps or to execute them successively.

15. The method according to claim 1, wherein the ambient energy converter is inserted into a housing 1.
